(19) United States
(12) Patent Application Publication
(10) Pub. No.: US 2012/0097240 A1
(43) Pub. Date: Apr. 26, 2012

(54) SOLAR CELL AND METHOD FOR THE PRODUCTION THEREOF

(75) Inventors: Benedikt Blasi, Freiburg (DE); Marius Peters, Singapore (SG); Jan Christoph Goldschmidt, Freiburg (DE); Martin Hermle, Freiburg (DE); Hubert Hauser, Freiburg (DE); Pauline Berger, Immenstaad (DE)

(73) Assignees: Fraunhofer-Gesellschaft Zur Förderung Der Angewandten Forschung E.V., Munchen (DE); ALBERT-LUDWIGS-UNIVERSITAT FREIBURG, Freiburg (DE)

(21) Appl. No.: 13/379,139

(22) PCT Filed: Jun. 7, 2010
(86) PCT No.: PCT/EP10/03396

§ 371 Date: Dec. 19, 2011

(30) Foreign Application Priority Data
Jun. 19, 2009 (DE) 102009029944.0

(51) Int. Cl. H01L 31/0232; H01L 31/18; H01L 31/0236

(52) U.S. Cl. 136/256; 438/71; 257/E31.13

(57) ABSTRACT

A solar cell, including a silicon substrate (1), a front side (2) designed for coupling light, and a rear side (3) is provided. It is essential that the front side, at least in a partial region, has a front side texture, which along a spatial direction A is periodic, the period length being greater than 1 μm, and that the rear side, at least in a partial region, has a rear side texture, which along a spatial direction B is periodic, with the period length being smaller than 1 μm. The spatial direction A is disposed at an 80° to 100° angle to the spatial direction B.

### BACKGROUND

The invention relates to a solar cell comprising a silicon substrate, a front side embodied for coupling light, and a rear side as well as a method for the production thereof.

Semiconductor—silicon solar cells serve to convert electromagnetic radiation impinging the solar cell into electric energy. For this purpose, light is coupled via the front side embodied for light coupling in the solar cell so that by absorption in the silicon substrate, pairs of electrons-holes are generated. The separation of the charge carriers occurs at a pn-junction. By an electric contact to a p and a n-section, the solar cell can be connected to an external circuit.

In addition to the electric features the luminous efficiency is essential for the effectiveness of a solar cell. The luminous efficiency represents the ratio between the electromagnetic radiation impinging the front side in reference to the overall generation of pairs of electrons-holes due to the light coupling in the solar cell.

Due to the fact that silicon is an indirect semiconductor and thus shows lower absorption values for incoming radiation in reference to direct semiconductors, particularly for silicon solar cells the extension of the light path inside the solar cell is relevant, in order to increase the luminous efficiency. Due to the low absorption features a portion of the light with longer wavelengths penetrates the solar cell and impinges the rear of the solar cell. It is therefore known for increasing the luminous efficiency to embody the rear side in a reflective fashion such that a light beam impinging the rear side is be reflected back in the direction to the front side.

In order to increase the luminous efficiency it is further known to increase the light coupling by a front side texture, for example in the form of inverted pyramids, because the impinging radiation reaches at least one additional surface of the front side upon an initial reflection such that the overall light coupling is increased. Additionally, a diagonal coupling of the light beams occurs so that in reference to a planar surface, a longer light path is yielded inside the silicon substrate prior to impinging the rear side and furthermore by the less acute angle when impinging the rear side the probability is higher for a total reflection at the rear side. The latter is particularly important when the rear side is reflective, for example by a layer of silicon oxide and a metallic layer thereupon.

A high-efficient silicon solar cell with a texture comprising inverted pyramids on the front side and a reflective rear side is described in DE 195 22 539 A1. Particularly in highly efficient wafer silicon solar cells a considerable increase of the luminous efficiency is yielded with a texture at the front side and a reflective rear side. However, due to the rules of radiation optics, the photons impinging the rear side are reflected directly to the front side so that a portion of the photons leave the solar cell again and thus cannot be used for energy conversion. This particularly relates to the long-wave photons and the thinner the solar cell the more distinct the loss.

Due to the essential components of the semiconductor material in the overall costs for the production of a solar cell the development of thinner, high-efficient silicon solar cells is imperative, though.

### SUMMARY

The invention is therefore based on the objective of providing a silicon solar cell and a method for production of such a solar cell, in which the luminous efficiency is increased, particularly in long-wave radiation.

This objective is attained in a solar cell according to the invention and in a method for the production of a solar cell according to the invention. Advantageous embodiments of the solar cell according to the invention and, advantageous embodiments of the method are described below and in the claims.

The solar cell according to the invention comprises a silicon substrate, a front side embodied for light coupling, and a rear side located opposite thereto.

It is essential that the front side at least in a partial section comprises a front side texture, which is periodical along a spatial direction A with a periodic length greater than 1 μm and the rear side comprising at least in a partial section a rear side texture, which is periodic in a spatial direction B with a period length shorter than 1 μm. Here, the spatial direction A forms an angle ranging from 80° to 100° in reference to the spatial direction B. In a top view to the front of the solar cell, the spatial directions A of the periodic extension of the front side texture and the spatial direction B of the periodic extension of the rear texture therefore form an angle ranging from 80° to 100°.

A texture is called periodic if a vector V (V≠0) exists, with: a translation by V and an integral multiple of V transfers the texture into itself. The creating vector of a period is the smallest possible vector V′ fulfilling said condition. Periodicity is only given if such a smallest possible vector exists. It applies for V′ that exclusively translations of V′ and integral multiples of V′ transfer the texture into itself. The length of V′ is the period length. If only one such vector exists (linearly independent) it is called linear periodicity. Preferably the front side and the rear side texture show linear periodicity.

The spatial direction A extends here parallel in reference to the front side and the spatial direction B parallel to the rear side. The characterization “parallel” relates here and in the following to an untextured surface of the front side and the rear side, i.e. virtual planar levels, which would represent said untextured front and/or rear sides. Typically the front side is parallel to the rear side. The statement “a spatial direction X extends parallel to a plane E” shall be understood such that the vector representing X is located in a plane E, thus all points of X are also points of E.

Contrary to the typical high-efficiency silicon solar cells, the solar cells according to the invention therefore comprise a texture both at the front as well as the rear side. However, it is essential that both textures have a different periodicity. This has the following reason:

Due to the absorption features of silicon, in silicon solar cells the wavelengths of the electromagnetic radiation that efficiently can be transferred into electric energy are in a range from 200 nm to 1,200 nm, with the absorption strongly reducing beginning at a typical cell thickness of approximately 1,000 nm. Periodic textures with a periodicity greater than 1 μm therefore show optic structures, which essentially are greater than the wavelength of the electromagnetic radiation. Such optic structures are therefore essentially refractive structures, i.e. the optic features can be described essentially by radiation optic. Here, the scope of the invention includes that the front side texture is coated with one or more optic layers, for example to reduce the reflection in reference to radiation impinging the front side.

The periodicity of the rear side texture is smaller than 1 μm, though. Due to the absorbing features of silicon in typical cell thicknesses from 10 μm to 250 μm only radiation with a wavelength greater than 800 nm penetrates the silicon substrate to the rear side so that the size of the optic structures of the rear side texture is in the range or smaller than the wavelength of the impinging electromagnetic radiation in silicon. Here, it must be observed that during propagation in silicon the wavelength of the light is reduced by a factor, which is equivalent to the refraction index, i.e. for silicon approximately by a factor of 3.5.

The rear side texture is therefore an essentially diffractive structure, i.e. the optic features of the rear side texture are essentially not described by geometrical optics but by wave optics.

The use of diffractive textures at the rear side of a solar cell is generally known and for example described in C. Heine, R. H. Morf, Submicrometer gratings for Solar energy applications. Applied Optics, VL, 34, no. 14, May 1995. In the silicon solar cells known from prior art no combination occurs of refractive and diffractive textures. Tests of the applicant have shown that the essential disadvantage is caused such that in combinations of a front side with a refractive texture and a rear side with a diffractive texture the light impinges at different directions and with various relative orientations on the rear side so that a portion of the radiation impinges on the rear side texture at an angle which is not ideal. Furthermore, the radiation diffracted at the rear side at least partially impinges the front side at unfavorable angles so that a decoupling of this radiation occurs and thus the luminous efficiency is reduced. This effect is particularly distinct when the front side structure represents a three-dimensional texture, such as a texture comprising inverted pyramids known from prior art.

For this reason, previously diffracted textures at the rear side of solar cells with refractive textures at the front side seemed not useful in the past.

However, the solar cell according to the invention comprises at the front side a texture periodically extending in the spatial direction A. This way, the potential directions and orientations are reduced by which the radiation impinges the rear side. Furthermore, the spatial direction B, in which the rear side texture extends periodically, shows an angle from 80° to 100° in reference to the spatial direction A. For the majority of the potential radiation paths here the previously described negative effect of shortening the light path is excluded.

Therefore, in the solar cell according to the invention for the first time a combination of an essentially refractive texture on the front side is realized with an essentially diffractive texture at the rear side such that the advantages of both types of texturing are combined and negative effects are excluded based on less than optimal incident angles for the diffractive structures of the rear side and the decoupling of radiation diffracted at the rear side to the texture of the front side.

Due to the embodiment of the texture of the front side as a texture periodically extending in the spatial direction A, at least in case of radiation impinging the front side perpendicularly, a coupling occurs essentially in a plane, which is stretched perpendicularly to the spatial direction of the front side. This way it is possible to optimize the diffractive rear side texture such
that the radiation diffracted at the rear side propagates almost parallel in reference to the rear side, leading to an extension of the light path,
that the radiation diffracted at the rear side impinges the front side such that the total reflection at the front side is achieved and thus also an extension of the light path, and
that at the rear side no multiple reflections occurs leading to loss.

Such an optimization is achieved, on the one hand, such that the spatial direction B, in which the rear side texture extends, shows an angle ranging from 80° to 100° in reference to the spatial direction A. An increased optimization is achieved by an angle ranging from 85° to 95°, preferably an angle of 90°, i.e. that the two spatial directions form a right angle.

Advantageously the textures of the front and the rear side each cover essentially the entire front and rear side of the solar cell, if applicable with interruptions e.g., to apply electroplating. The scope of the invention also includes that only one or more partial sections of the front and/or rear side show a texture. In this embodiment, front and rear side structures are provided, arranged preferably at opposite partial sections of the front and rear side.

The scope of the invention also includes that perhaps the solar cell at the front and/or the rear side are divided into several partial sections, each of which have a periodically extending texture. However, it is essential that in other spatial directions than the spatial direction of the periodic extension perhaps repetitions given have an essentially larger periodicity compared to the periodicity of the periodically extending texture.

Thus, preferably, the texture of the front side has no periodicity in a spatial direction A′ perpendicularly in reference to a spatial direction A or a periodicity with a period length of at least 30 μm, preferably at least 50 μm. The spatial direction A′ also extends parallel to the front side. Furthermore, it is beneficial for the front side texture in the spatial direction A′ showing no periodicity or a periodicity with a period length equivalent to at least the 5-fold, preferably at least the 10-fold, further preferred at least the 15-fold the period length of the front side texture in the spatial direction A.

Furthermore, preferably the rear side texture has in a spatial direction B′ perpendicular in reference to a spatial direction B no periodicity or a periodicity with a period length of at least 5 μm, preferably at least 10 μm, further preferred at least 30 μm, particularly at least 50 μm. The spatial direction B′ also extends parallel to the rear side. Further it is beneficial when the rear side texture has no periodicity in the spatial direction B′ or a periodicity with a period length equivalent to at least the 5-fold, preferably at least the 10-fold, further preferred at least the 15-fold of the period length of the rear side texture in the spatial direction B.

Furthermore, it is advantageous when the textures has no or only minor changes in elevation in the spatial directions A′ and/or B′, i.e. that the elevation profile of the texture in this spatial direction does not change or only slightly.

Preferably the elevation of the front side texture changes in the spatial direction A′ only by no more than 2 μm, and particularly the front side texture has an approximately constant height in the spatial direction A′.

Furthermore, the height of the rear side texture preferably changes in the spatial direction A′ by no more than 50 nm, particularly the rear side texture has an approximately constant height in the spatial direction A′.

The above-stated conditions simplify the production process and prevent disadvantageous optic effects.

In order to simplify the production and reduce the costs of the solar cell according to the invention it is particularly advantageous that the front side texture is a texture extending linearly in the spatial direction A′ and /or the rear side is a texture extending linearly in the spatial direction B′. Such structures are also called groove structures. In this case, the spatial direction of the period extension is therefore perpendicular in reference to the linear or groove-like texture elements. In particular it is beneficial that the front side texture in the spatial direction Al and/or the rear side texture in the spatial direction B′ each have an approximately constant cross-sectional area and an approximately constant cross-sectional shape.

The scope of the invention includes that in partial sections at the front and/or rear side the texture is interrupted, for example to apply electroplating for an electric contacting of the silicon substrate.

The elevation of the front side texture, i.e. the maximal difference in height of the optically relevant surface of the front side texture preferably ranges from 2 μm to 50 μm, particularly from 5 μm and 30 μm. This way, an optimization of the refractive optic effect and the cost-effective production is yielded.

The height of the rear side texture, i.e. the maximum difference in elevation of the optically relevant area of the rear side texture ranges preferably from 50 nm to 500 nm, particularly from 80 nm to 300 nm. This way, an optimization is yielded of the diffractive optic effect and the cost-effective production.

In order not to compromise the electric features of the solar cell and to allow a simple electric contacting via metallic structures it is advantageous when the front side texture has a periodicity of less than 40 μm, preferably less than 20 μm.

In order to yield ideal optic features of the rear side it is alternatively and/or additionally advantageous that the rear side texture has a periodicity greater than 50 nm, preferably greater than 100 nm.

Preferably the front side texture is created directly at the front of the silicon substrate. Thus, the scope of the invention includes to apply one or more layers on the front side of the silicon substrate and to create the texture at one or more of these layers. The same applies for the rear side texture.

The periodicities of the front side texture and the rear side texture are preferably selected such that the front side texture has a primarily refractive texture and the rear side texture has a primarily diffractive texture. Advantageously the periodicity of the front side is therefore greater than 3 μm, particularly greater than 5 μm. Alternatively or additionally, advantageously the periodicity of the rear side texture is smaller than 800 nm, preferably smaller than 600 nm.

For an optimal increase of the luminous efficiency the front side texture advantageously covers at least 30%, particularly at least 60%, further at least 90% of the front side, if applicable with interruptions, e.g., for electroplating. The same applies for the rear side texture.

In order to create high-efficient silicon solar cells the use of a mono-crystalline silicon substrate is common. In this case, the front side texture is preferably embodied by linear texture elements, each of which comprising a triangular cross-sectional surface.

Additionally, the use of multi-crystalline silicon wafers is advantageous. Here, the levels of efficiency yielded are slightly lower in reference to mono-crystalline solar cells, however the material costs are considerably lower, too. When using multi-crystalline silicon wafers advantageously a front side structure is created with a cross-sectional area having curved or round edges.

Due to the different etching speeds in different spatial directions during the etching of mono-crystalline silicon substrates the structure of the rear side preferably has linear texture elements, such as described in the above-mentioned publication J. Heine; R. H. Morf, 1.c. on page 2478 concerning FIG. 3. However, frequently the production of such texture elements with a serrated cross-section is very complicated and expensive. Preferably the serration is therefore similar to the shape of stairs, as described in the above-mentioned publication on the same page concerning FIG. 4. The above-mentioned publication is incorporated in the description here by reference.

A particularly simple and thus cost-effectively produced diffractive texture is provided in a crenellate texture on the rear side with sides perpendicularly in reference to each other, such as described for example in the above-mentioned publication concerning FIG. 2.

Additionally, sinusoidal-shaped diffractive textures as well as serrated diffractive textures are included in the scope of the invention.

Due to the low structural sizes of the rear side texture noted above, advantageous cross-sectional shapes can frequently be achieved only approximated for technical reasons, particularly frequently rounding occurs at the edges of the structures.

In order to simplify the further processing steps at the rear side of the solar cell according to the invention, particularly the application of electro-plating, it is advantageous that at the rear side a layer is applied on the rear side texture, preferably a dielectric layer. Here, the rear side texture is covered entirely by the dielectric layer so that a planar surface is given at the rear side for the subsequent processing steps. It is particularly advantageous that the layer of the rear side is an electrically isolating layer and that electro-plating is applied onto the layer of the rear side, preferably over the entire surface.

This way it is easily possible to create local electrically conductive connections between the metal layer and the silicon substrate by local melting, for example by way of a laser.

Different from the known diffractive textures of the rear side, in the solar cell according to the invention, due to the front side texture, the radiation typically impinges the rear side not perpendicularly. Thus, preferably the rear side texture is therefore optimized for a non-perpendicular irradiation of the rear side, particularly by selecting for a given irradiation angle θ upon the rear side, the periodicity Λ_{R} of the rear side texture according to the formula 1:

$${Λ}_{R} = \frac{λ}{n cos ( θ )} \qquad ( formula 1 )$$

with the diffraction index n of the silicon substrate and the wavelength λ of the beam impinging the rear side. Preferably, λ represents here the greatest relevant wavelength, i.e. the greatest contributing wavelength of the spectrum of the radiation impinging the solar cell still relevant for generating charge carriers and the angle 0 is the primary incident angle of the radiation to the rear side, due to the structure given at the front side. Formula 1 particularly provides an optimal periodicity for the rear side texture at an angle of 90° between the periodic extension of the texture of the front and rear side and/or at a texture of the front side with triangular cross-sectional areas.

When using a mono-crystalline silicon wafer and etching the front side texture, due to the orientation of the crystals, typically an incident angle θ of 41.4° develops on the rear side. Furthermore, for silicon the greatest relevant wavelength is preferably selected with λ=1100 nm, because this represents a wavelength similar to the band gap. With a refraction index of n=3.5 for silicon, in this preferred embodiment here a periodicity develops of Λ_{R}=419 nm.

The invention further comprises a method for producing a solar cell, comprising a silicon substrate with a front and a rear side according to claim 13. The method according to the invention comprises the following processing steps:

In a processing step A, a front side texture is created at least at a partial section of the front side; with the front side texture being parallel in a spatial direction invariant parallel to the front side and in a spatial direction A perpendicular in reference thereto and comprising a periodicity greater than 1 μm parallel to the front side.

Preferably, subsequently a cleaning of the rear of the semiconductor substrate occurs.

In a processing step B, a rear side texture is created at least over a partial section of the rear side, with the rear side texture being invariant to a spatial direction parallel in reference to the rear side and comprising a periodicity of less than 1 μm in a perpendicular spatial direction B parallel to the rear side.

Here, the textures of the front and the rear side are embodied such that the spatial direction A forms an angle from 80° to 100° in reference to the spatial direction B.

Preferably the creation of the rear side texture in the processing step B comprises the following processing steps:

In a processing step B1 an etch-resistant masking layer is applied on the rear side. Subsequently in a processing step B2 the masking layer is structured via an embossing method. Such an embossing method is described for example in U.S. Pat. No. 4,731,155. Subsequently, in a processing step B3, etching occurs of the sections of the rear side not covered by the masking layer.

Subsequently the masking layer is removed.

In another advantageous embodiment of the method according to the invention subsequently in a step C, a layer is applied to the rear side, preferably a dielectric layer, onto the rear side texture, with the layer of the rear side completely covering the rear side texture.

The layer of the rear side is preferably covered over the entire area with a metallic layer. For the production of the electric contacts for the rear side then a known method of locally melting can be applied using a laser (laser-fired contacts (LFC)), as described in DE 100 46 170 A1.

The structure of the solar cell according to the invention may be transferred onto the structures of the solar cell, with the front and the rear sides having the textures of the solar cell according to the invention. Typically the solar cell according to the invention comprises at least at the front side of the silicon substrate an emitter and at the rear side electroplating for contacting emitters as well as on the rear side electroplating for basic contacting. In particular, a structure similar to the solar cell described in DE 195 22 539 A1 is beneficial, with the textures applied at the front and the rear side of the silicon substrate are embodied according to the solar cell according to the invention. Additionally, the solar cell according to the invention may be embodied analogous to the known rear side—contract cells (such as described in U.S. Pat. No. 5,053,058), particularly EWT-solar cells (such as described in U.S. Pat. No. 5,468,652) or MWT solar cells (such as described in EP985233).

### BRIEF DESCRIPTION OF THE DRAWINGS

Additional features and advantageous embodiments are discernible from the exemplary embodiment described in the following and illustrated in the figures. Here, shown are:

FIG. 1 a detail of a solar cell according to the invention in a schematic, perspective view, and

FIG. 2 cross-sectional views of FIG. 1.

### DETAILED DESCRIPTION OF THE PREFERRED EMBODIMENTS

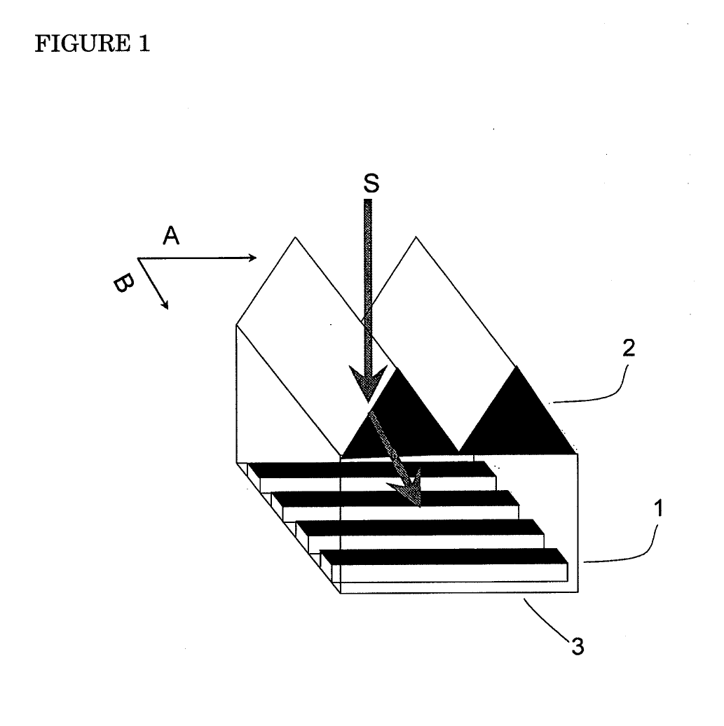

The solar cell shown in FIG. 1 comprises a silicon substrate 1 with a front side 2 and a rear side 3.

The silicon substrate is a mono-crystalline silicon wafer. At the front side 2, a refractive front structure with triangular cross-sectional areas is provided and at the rear side 3 a diffractive rear side texture is embodied, showing a crenellate cross-section.

The front side structure is embodied as a linear texture with texture elements arranged parallel in reference to each other, with the texture extending periodically along the spatial direction marked A. The structure of the rear side is also embodied as a linear structure, with the texture extending periodically along the spatial direction marked B. The spatial directions A and B form an angle of 90°.

In the exemplary embodiment of a solar cell according to the invention shown in FIG. 1 a beam S perpendicularly impinging the front side 1 is coupled at the front side 2 diagonally into the silicon substrate 1. Here, the beam S extends in the silicon substrate in a plane parallel to the linear structures at the rear side, and thus perpendicularly in reference to the periodic extension (spatial direction B) of the rear side texture.

The beam diffracted at the rear side propagates however such that upon the beam impinging the silicon substrate 1 at the front side 2 a total reflection occurs and thus no portion of the beam is decoupled.

The illustration in FIG. 1 serves to clarify the geometric arrangement of the textures at the front and rear side. The size of the textures in reference to each other and in reference to the overall thickness of the solar cell shown are not according to scale, for better visibility. Furthermore, for better illustration the triangular cross-section of the front texture and the lower lying surfaces of the rear side texture are shown filled.

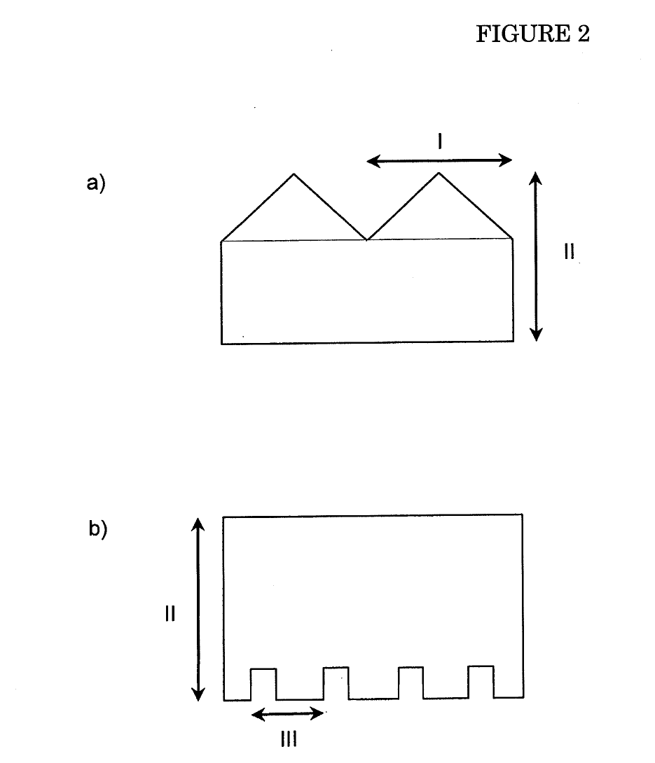

FIG. 2 shows cross-sections of FIG. 1. Here, FIG. 2a) shows a section perpendicular to the front side 2 and parallel to the spatial direction A; FIG. 2b) shows a cross-section perpendicular to the front side 2 and parallel to the spatial direction B.

The solar cell illustrated according to the invention has a silicon substrate with a total thickness II of 250 μm, with the height of the texture elements at the front amounts to approximately 14 μm. The height of the texture elements at the rear side amounts to approximately 0.1 μm.

The front side texture has a periodicity of 10 μm, i.e. the distance I in FIG. 2a) amounts to 10 μm. The periodicity of the rear side texture is approximately 419 nm, i.e. the distance III in FIG. 2b) amounts to approximately 419 nm.

1. A solar cell, comprising a silicon substrate (1), with a front side (2) and a rear side (3) embodied for light coupling, the front side comprises at least in a partial section a front side texture, which is periodic along a spatial direction A with a period length greater than 1 μm and the rear side comprises a rear side texture at least in a partial section, which is periodic with a period length smaller than 1 μm along a spatial direction B, with the spatial direction A having an angle from 80° to 100° in reference to the spatial direction B.

2. A solar cell according to claim 1, wherein the spatial direction A has an angle from 85° to 95°, in reference to the spatial direction B.

3. A solar cell according to claim 1, wherein in a spatial direction A′ perpendicular in reference to the spatial direction A, the front side texture has at least one of no periodicity or a periodicity with a period length of at least 30 μm, or in the spatial direction A′ a height of the front side texture changes by no more than 2 μm, in the spatial direction A′.

4. A solar cell according to claim 1, wherein in a spatial direction B′ perpendicular in reference to the spatial direction B the rear side texture has at least one of no periodicity or a periodicity with a period length of at least 5 μm, or that in the spatial direction B′ a height of the rear side texture changes by no more than 50 nm or that in the spatial direction B′ a structure of the rear side shows no periodicity or a periodicity with a period length at least 5-fold, in the spatial direction B.

5. A solar cell according to claim 1, wherein at least one of the front side texture is a texture extending linearly in a spatial direction A′, perpendicular in reference to the spatial direction A, or the rear side texture is a texture extending linearly in a spatial direction B′ perpendicular to the spatial direction B, and the front side texture in the spatial direction A′ or the rear side texture in the spatial direction B′ each has an approximately constant cross-sectional area and an approximately constant form of the cross-sections.

6. A solar cell according to claim 5, wherein at least one of the front side texture is a refractive texture or the rear side texture is a diffractive texture.

7. A solar cell according to claim 1, wherein at least one of the periodicity of the front side texture is greater than 3 μm, or the periodicity of the rear side texture is smaller than 800 nm.

8. A solar cell according to claim 1, wherein the solar cell comprises a mono-crystalline silicon substrate (1), with the front texture being embodied at the front side (2) and the front side texture has triangular cross-sectional surfaces.

9. A solar cell according to claim 1, wherein the solar cell comprises a multi-crystalline silicon substrate (1), with the front side texture being embodied on the front side (2) and the cross-sectional surfaces of the front side texture having parabolic limits or arc sections.

10. A solar cell according to claim 1, wherein the rear side texture has an at least approximately serrated or stair-like cross-section.

11. A solar cell according claim 1, wherein the rear side texture has a crenellate cross-section.

12. A solar cell according to claim 1, wherein the front side (2) comprises one or more optic layers with a thickness of less than 1 μm, in order to increase the light coupling to the front side (2).

13. A solar cell according to claim 1, wherein at least one of the front side texture is embodied on all of the front side (2) or the rear side texture is embodied on all of the rear side (3) of the silicon substrate.

14. A solar cell according to claim 1, wherein a rear layer is provided on the rear side (3) applied on the rear side texture, with the rear side texture being completely covered by the dielectric layer.

15. A solar cell according to claim 14, wherein a metallic layer is applied on the rear layer of the rear side and comprises a multitude of electrically conductive connections to the rear side texture.

16. A method for producing a solar cell with a semiconductor substrate with a front and a rear side (3), comprising the following steps A—creating a front side texture at least on a partial section of the front side, with the front side texture being periodic along a spatial direction A with a period length greater than 1 μm,
B—creating a rear side texture at least on a partial section of the rear side, periodic along a spatial direction B with a period length smaller than 1 μm, with the spatial direction A forming an angle from 80° to 100° in reference to the spatial direction B.

17. A method according to claim 16, wherein the creation of the rear side texture in the processing step B comprises the following processing steps:
B1—applying an acid-resistant masking layer;
B2—structuring the masking layer via an embossing process, and
B3—etching the section of the rear side (3) not covered by the masking layer.

18. A method according to claim 17, wherein after step B a rear side layer is applied on and completely covers the rear side texture.

19. A method according to claim 18, wherein a metallic layer is applied on the rear side (3) or the layers covering the rear side (3) and the metallic layer is connected at a multitude of points electrically conductive to the semiconductor substrate.
